(19) United States
(12) Patent Application Publication
(10) Pub. No.: US 2017/0324393 A1
(43) Pub. Date: Nov. 9, 2017

(54) Radio Frequency Duplexer

(71) Applicant: Huawei Technologies Co., Ltd., Shenzhen (CN)

(72) Inventor: Udo Karthaus, Munich (DE)

(21) Appl. No.: 15/632,758

(22) Filed: Jun. 26, 2017

Related U.S. Application Data
(63) Continuation of application No. PCT/EP2015/067075, filed on Jul. 24, 2015.

(51) Int. Cl. H03H 7/46; H01P 5/18; H03H 7/01; H04B 1/52; H03F 3/19; H03F 3/21

(52) U.S. Cl. CPC H03H 7/463; H03F 3/19; H03F 3/21; H03H 7/0153; H04B 1/52; H01P 5/184; H03F 2200/255; H03F 2200/451; H03H 2210/025; H03F 2200/294

(57) ABSTRACT

A radio frequency duplexer with a first directional coupler configured to divide an input reception signal into a first auxiliary reception signal and a second auxiliary reception signal, where the first auxiliary reception signal and the second auxiliary reception signal comprise signal components at a reception frequency, a first filter configured to filter the first auxiliary reception signal to obtain a third auxiliary reception signal, a second filter configured to filter the second auxiliary reception signal to obtain a fourth auxiliary reception signal, where pass bands of the first and the second filters comprise the reception frequency, a second directional coupler configured to combine the third auxiliary reception signal with the fourth auxiliary reception signal to obtain an output reception signal.

### CROSS-REFERENCE TO RELATED APPLICATIONS

This application is a continuation application of International Patent Application No. PCT/EP2015/067075, filed on Jul. 24, 2015, the disclosure of which is hereby incorporated herein by reference in its entirety.

### TECHNICAL FIELD

The disclosure relates to the field of radio frequency duplexers and, in particular, to integrated radio frequency duplexers.

### BACKGROUND

Radio frequency (RF) duplexers are major components in RF systems, such as mobile communication systems or radar systems, and are used for a large variety of applications. RF duplexers allow a bi-directional duplex signal transmission over a transmission channel, wherein a receiver can be isolated from a transmitter while sharing a common antenna.

Conventional RF duplexers are implemented using large resonators or filters, e.g. surface-acoustic-wave (SAW) or bulk-acoustic-wave (BAW) filters. These RF duplexers may not be integrated on a single semiconductor substrate, and may not be tunable for covering different frequency bands.

Other conventional RF duplexers are based on RF transformers, wherein no filtering is typically applied. Transformer-based RF duplexers are usually very sensitive to antenna impedance variations, and induce a 3 decibel systematic loss in addition to a resistive loss within the RF duplexer.

In U.S. Pat. App. Pub. No. US2013083703A1, a RF duplexer is described using simple filters, wherein transmission frequencies may be higher than reception frequencies, thus leading to a reduced number of applicable frequency bands.

### SUMMARY

It is an object of the invention to provide an efficient and flexible RF duplexer.

This object is achieved by the features of the independent claims. Further implementation forms are apparent from the dependent claims, the description and the figures.

The invention is based on the finding that an architecture utilizing two filters and two directional couplers can be used, wherein a reception path can be realized by passing a reception signal through the filters, and wherein a transmission path can be realized by reflecting a transmission signal at the filters. The RF duplexer can connect a transmission port and a reception port to an antenna port, while providing a high isolation between the transmission port and the reception port. The RF duplexer can have a low sensitivity with regard to variations of antenna impedance, and can be tunable to different frequency bands, e.g. defined by the 3^{rd} generation partnership project (3GPP). Furthermore, a high amount of blocker filtering can be provided, and power losses in the transmission and reception paths can be kept low.

The RF duplexer can be implemented as an integrated circuit, which can be realized using semiconductor technology. The RF duplexer can be regarded as a tunable integrated duplex filter, and can be applied within any RF system, such as a mobile communication system or a radar system.

According to a first aspect, the invention relates to a RF duplexer for handling an input reception signal, the RF duplexer comprising a first directional coupler being configured to divide the input reception signal into a first auxiliary reception signal and a second auxiliary reception signal, wherein the first auxiliary reception signal and the second auxiliary reception signal comprise signal components at a reception frequency, a first filter being configured to filter the first auxiliary reception signal to obtain a third auxiliary reception signal, wherein a pass band of the first filter comprises the reception frequency, a second filter being configured to filter the second auxiliary reception signal to obtain a fourth auxiliary reception signal, wherein a pass band of the second filter comprises the reception frequency, and a second directional coupler being configured to combine the third auxiliary reception signal with the fourth auxiliary reception signal to obtain an output reception signal. Thus, an efficient and flexible RF duplexer can be provided. The RF duplexer can realize a frequency duplexing.

The RF duplexer can be configured to handle input reception signals comprising signal components at a plurality of frequencies, e.g. comprising blockers, wherein said reception frequency is the intended reception frequency of the RF duplexer. The first filter and the second filter can have a low transmission loss at the reception frequency.

In a first implementation form of the RF duplexer according to the first aspect as such, the first directional coupler is configured to divide an input transmission signal into a first auxiliary transmission signal and a second auxiliary transmission signal, wherein the first auxiliary transmission signal and the second auxiliary transmission signal comprise signal components at a transmission frequency, the first filter is configured to reflect the first auxiliary transmission signal to obtain a third auxiliary transmission signal, wherein a stop band of the first filter comprises the transmission frequency, the second filter is configured to reflect the second auxiliary transmission signal to obtain a fourth auxiliary transmission signal, wherein a stop band of the second filter comprises the transmission frequency, and the first directional coupler is configured to combine the third auxiliary transmission signal with the fourth auxiliary transmission signal to obtain an output transmission signal. Thus, an input transmission signal can efficiently be handled by the RF duplexer.

The RF duplexer allows for a mitigation of a 3 decibel (dB) loss limit, wherein the 3 dB loss limit indicates a limit of transmission loss and reception loss. Compared to transformer-based duplexers, where the sum of transmission loss and reception loss is typically at least 6 dB, a considerable improvement can be realized. The first filter and the second filter can have a low return loss at the transmission frequency.

In a second implementation form of the RF duplexer according to the first aspect as such or the first implementation form of the first aspect, the first directional coupler and/or the second directional coupler is a quadrature hybrid coupler. Thus, the first directional coupler and/or the second directional coupler can be implemented efficiently.

The quadrature hybrid coupler can provide one isolated port, wherein two ports can have a relative phase shift of 90 degree and a respective attenuation of 3 dB.

In a third implementation form of the RF duplexer according to the first aspect as such or any preceding implementation form of the first aspect, the first filter and/or the second filter is a band-pass filter, a low-pass filter, a high-pass filter, or a notch filter. Thus, the first filter and/or the second filter can be implemented efficiently.

The band-pass filter can have one pass band and two stop bands. The low-pass filter can have one pass band and one stop band, wherein the pass band comprises lower frequencies than the stop band. The high-pass filter can have one pass band and one stop band, wherein the pass band comprises higher frequencies than the stop band. The notch filter relates to a band-stop filter, which can have two pass bands and one stop band, wherein the stop band has a narrow frequency bandwidth. The first filter and/or the second filter can be realized as low order filters, e.g. first or second order filters.

In a fourth implementation form of the radio frequency duplexer according to the first aspect as such or any preceding implementation form of the first aspect, the first directional coupler and the second directional coupler are identical, and/or the first filter and the second filter are identical. Thus, symmetry conditions within the RF duplexer can be exploited.

The symmetry conditions can result in constructive and/or destructive interference of signals within the RF duplexer. Therefore, a high isolation between respective ports and a low loss can be realized.

In a fifth implementation form of the RF duplexer according to the first aspect as such or any preceding implementation form of the first aspect, the RF duplexer further comprises a tunable load being connected to the second directional coupler, the tunable load having a variable impedance. Thus, imperfections and/or imbalances within the RF duplexer, e.g. due to mismatching, can be compensated efficiently. The tunable load can be tuned in dependence of an impedance of an antenna tuner or an antenna.

In a sixth implementation form of the RF duplexer according to the first aspect as such or any preceding implementation form of the first aspect, the first directional coupler and/or the second directional coupler is tunable. Thus, an efficient adaption of the RF duplexer to different frequency bands, e.g. 3GPP frequency bands, can be realized.

In a seventh implementation form of the RF duplexer according to the sixth implementation form of the first aspect, the first directional coupler and/or the second directional coupler comprises a plurality of digitally tunable capacitors. Thus, different frequency bands, e.g. 3GPP frequency bands, can be selected efficiently. The first directional coupler and/or the second directional coupler can further comprise a plurality of inductors.

The digitally tunable capacitors can be implemented using silicon-on-insulator (SOI) and/or micro-electro-mechanical-system (MEMS) technology. The inductors can be implemented using silicon-on-insulator (SOI), integrated-package-device (IPD), and/or surface-mount-device (SMD) technology. The digitally tunable capacitors and the inductors can further be implemented using bulk complementary-metal-oxide-semiconductor (CMOS) technology, wherein the performance with regard to quality (Q) factors and linearity may be considered.

In an eighth implementation form of the RF duplexer according to the first aspect as such or any preceding implementation form of the first aspect, the first filter and/or the second filter is tunable. Thus, an efficient adaption of the RF duplexer to different frequency bands, e.g. 3GPP frequency bands, can be realized.

In a ninth implementation form of the RF duplexer according to the eighth implementation form of the first aspect, the first filter and/or the second filter comprises a further plurality of digitally tunable capacitors. Thus, different frequency bands, e.g. 3GPP frequency bands, can be selected efficiently. The first filter and/or the second filter can further comprise a further plurality of inductors.

The digitally tunable capacitors can be implemented using SOI and/or MEMS technology. The inductors can be implemented using IPD, SMD, SAW, and/or BAW technology.

In a tenth implementation form of the RF duplexer according to the first aspect as such or any preceding implementation form of the first aspect, the first directional coupler, the second directional coupler, the first filter, and/or the second filter comprises a plurality of transmission lines. Thus, the RF duplexer can be implemented efficiently.

The transmission lines can be quarter-wavelength (λ/4) transmission lines and/or slow-wave transmission lines. The transmission lines can e.g. be realized as microstrips, striplines, or coplanar waveguides on a monolithic microwave integrated circuit (MMIC).

According to a second aspect, the invention relates to a RF frontend, the RF frontend comprising a RF duplexer according to the first aspect as such or any implementation form of the first aspect, the RF duplexer being configured to handle an input reception signal and to provide an output reception signal, and a low-noise amplifier being configured to amplify the output reception signal. Thus, an efficient and flexible RF frontend can be provided.

The RF frontend can take advantage of the specific characteristics of the RF duplexer. The RF frontend can be realized on a single MMIC. The RF frontend can form a RF frontend module (FEM).

The RF frontend can further comprise an antenna tuner and/or an antenna, wherein the antenna tuner can be connected to the antenna. The antenna tuner can be configured to match an impedance of the antenna to an impedance of the RF duplexer. The input reception signal can be provided by the antenna tuner or by the antenna.

In a first implementation form of the RF frontend according to the second aspect as such, the RF frontend further comprises a power amplifier being configured to provide an input transmission signal, wherein the RF duplexer is configured to handle the input transmission signal and to provide an output transmission signal. Thus, an input transmission signal can efficiently be provided by the RF frontend.

In a second implementation form of the RF frontend according to the second aspect as such or the first implementation form of the second aspect, the RF frontend further comprises a RF switch being configured to route the output reception signal from the RF duplexer to the low-noise amplifier. Thus, the RF frontend can be operated efficiently.

The RF frontend can comprise a further RF switch for routing the input reception signal from an antenna tuner and/or an antenna to the RF duplexer. The RF frontend can comprise additional RF switches for routing the input transmission signal and/or the output transmission signal. The RF frontend can consequently comprise at least one RF switch.

Using a RF switch can particularly be advantageous if the RF frontend comprises at least one, preferably more than one, low-noise amplifier.

According to a third aspect, the invention relates to a method for handling an input reception signal, the method comprising dividing, by a first directional coupler, the input reception signal into a first auxiliary reception signal and a second auxiliary reception signal, wherein the first auxiliary reception signal and the second auxiliary reception signal comprise signal components at a reception frequency, filtering, by a first filter, the first auxiliary reception signal to obtain a third auxiliary reception signal, wherein a pass band of the first filter comprises the reception frequency, filtering, by a second filter, the second auxiliary reception signal to obtain a fourth auxiliary reception signal, wherein a pass band of the second filter comprises the reception frequency, and combining, by a second directional coupler, the third auxiliary reception signal with the fourth auxiliary reception signal to obtain an output reception signal. Thus, an efficient and flexible duplexing can be provided. The method can realize a frequency duplexing.

The method can be performed by the RF duplexer and/or the RF frontend. Further features of the method directly result from the functionality of the RF duplexer and/or the RF frontend.

In a first implementation form of the method according to the third aspect as such, the method further comprises dividing, by the first directional coupler, an input transmission signal into a first auxiliary transmission signal and a second auxiliary transmission signal, wherein the first auxiliary transmission signal and the second auxiliary transmission signal comprise signal components at a transmission frequency, reflecting, by the first filter, the first auxiliary transmission signal to obtain a third auxiliary transmission signal, wherein a stop band of the first filter comprises the transmission frequency, reflecting, by the second filter, the second auxiliary transmission signal to obtain a fourth auxiliary transmission signal, wherein a stop band of the second filter comprises the transmission frequency, and combining, by the first directional coupler, the third auxiliary transmission signal with the fourth auxiliary transmission signal to obtain an output transmission signal. Thus, an input transmission signal can efficiently be handled.

The invention can be applied within any RF system, such as a mobile communication system or a radar system.

### BRIEF DESCRIPTION OF EMBODIMENTS

Embodiments of the invention will be described with respect to the following figures, in which:

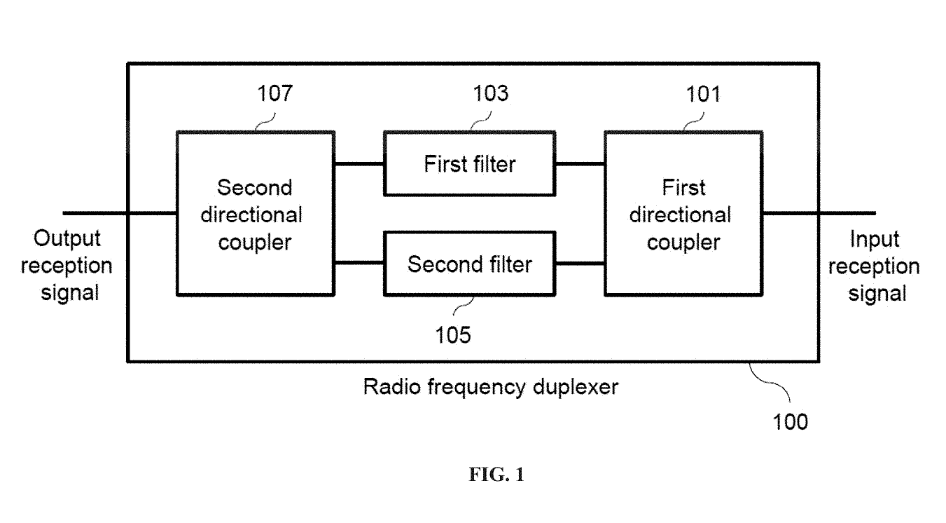

FIG. 1 shows a diagram of a RF duplexer according to an embodiment;

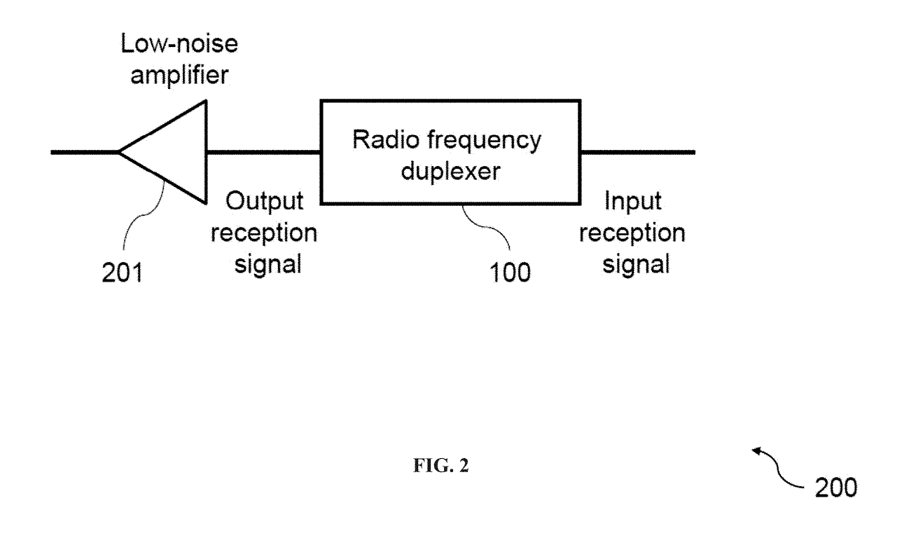

FIG. 2 shows a diagram of a RF frontend according to an embodiment;

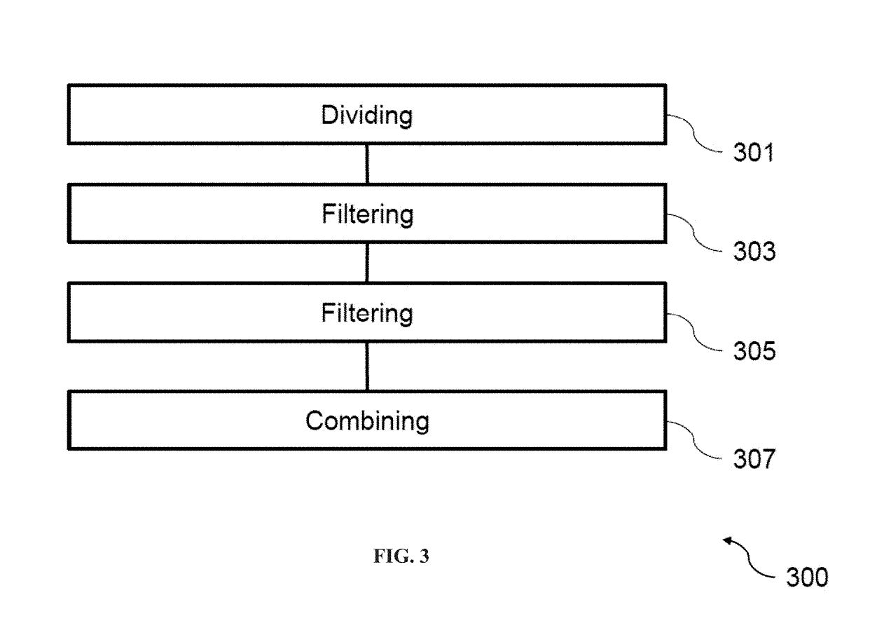

FIG. 3 shows a diagram of a method according to an embodiment;

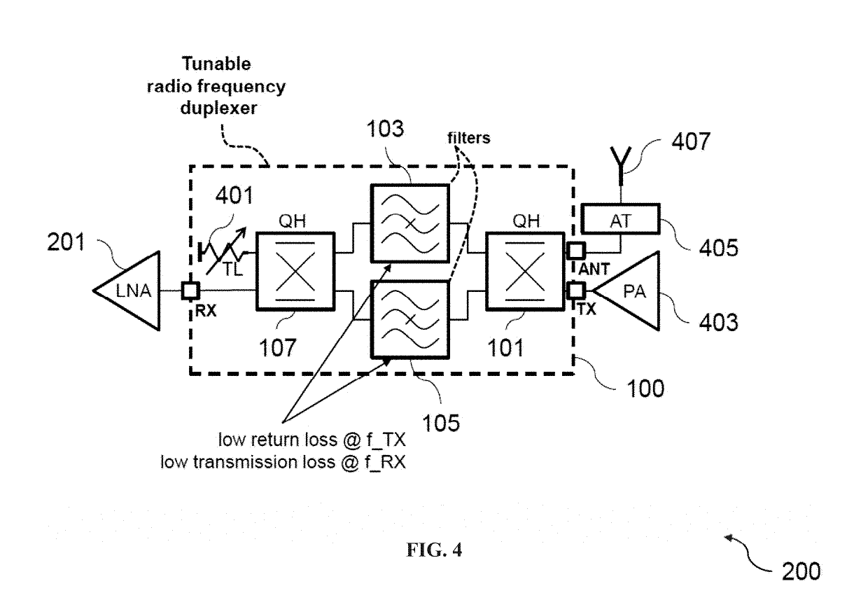

FIG. 4 shows a diagram of a RF frontend according to an embodiment;

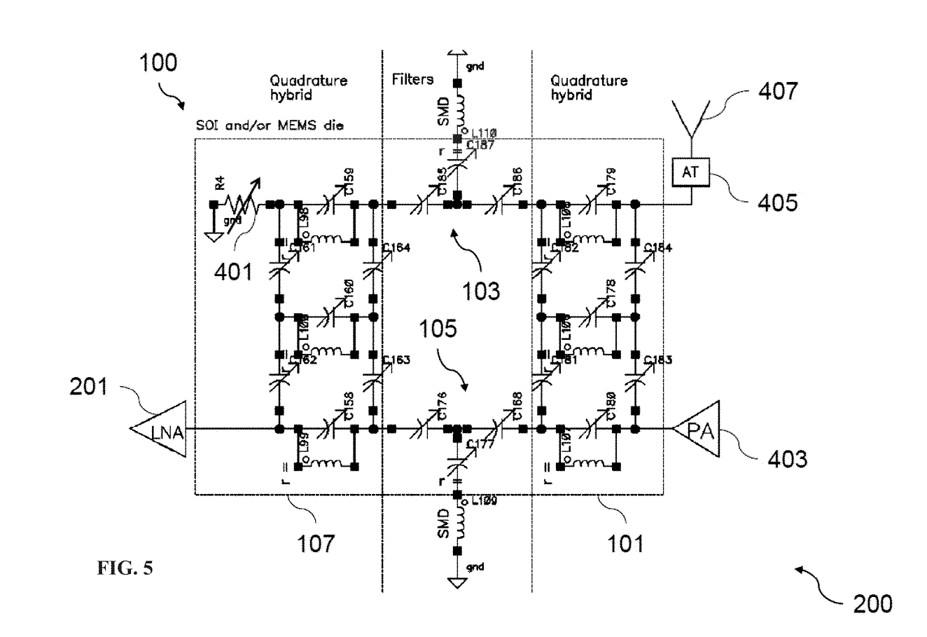

FIG. 5 shows a diagram of a RF frontend according to an embodiment;

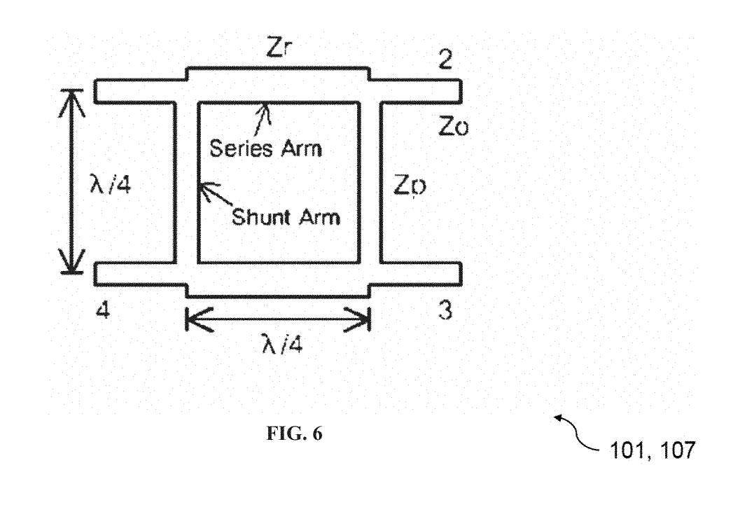

FIG. 6 shows a diagram of a first directional coupler and/or a second directional coupler according to an embodiment;

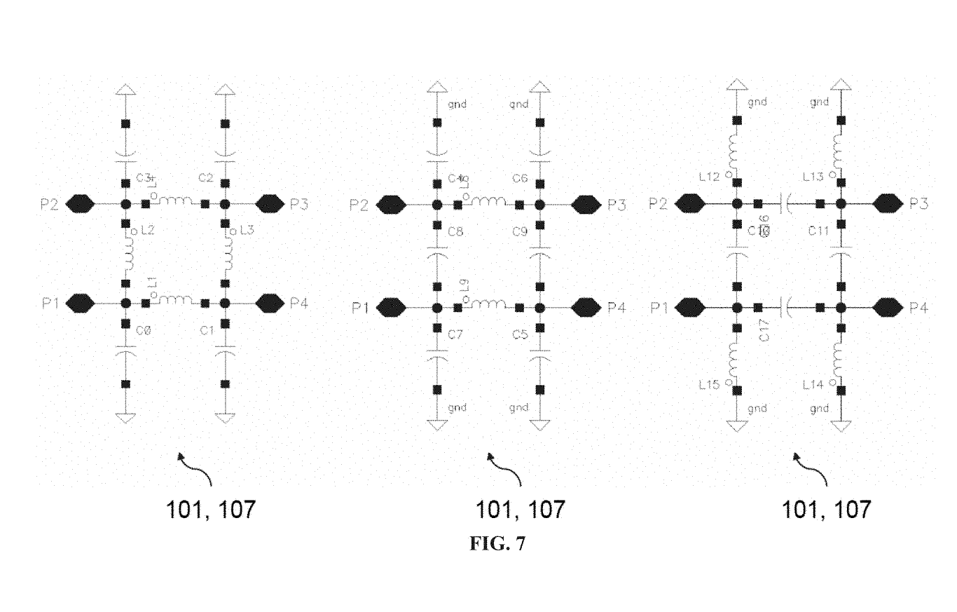

FIG. 7 shows diagrams of a first directional coupler and/or a second directional coupler according to different embodiments;

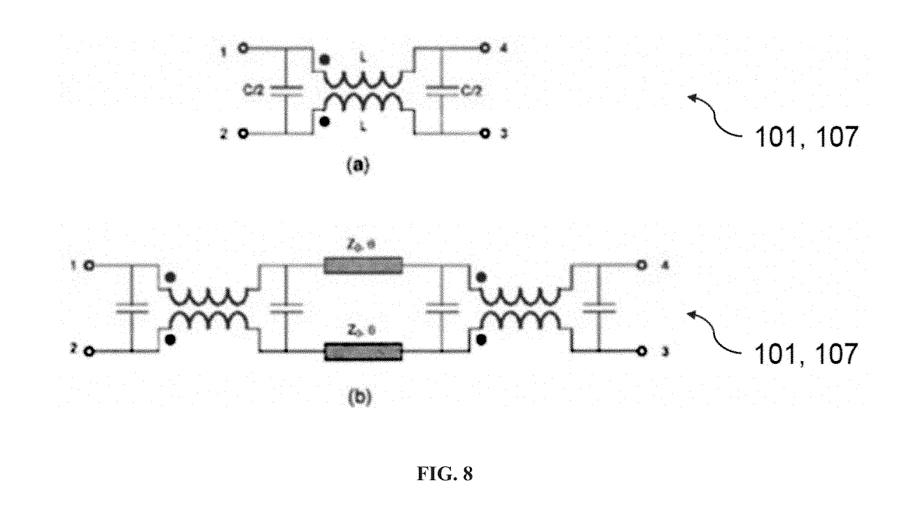

FIG. 8 shows diagrams of a first directional coupler and/or a second directional coupler according to different embodiments;

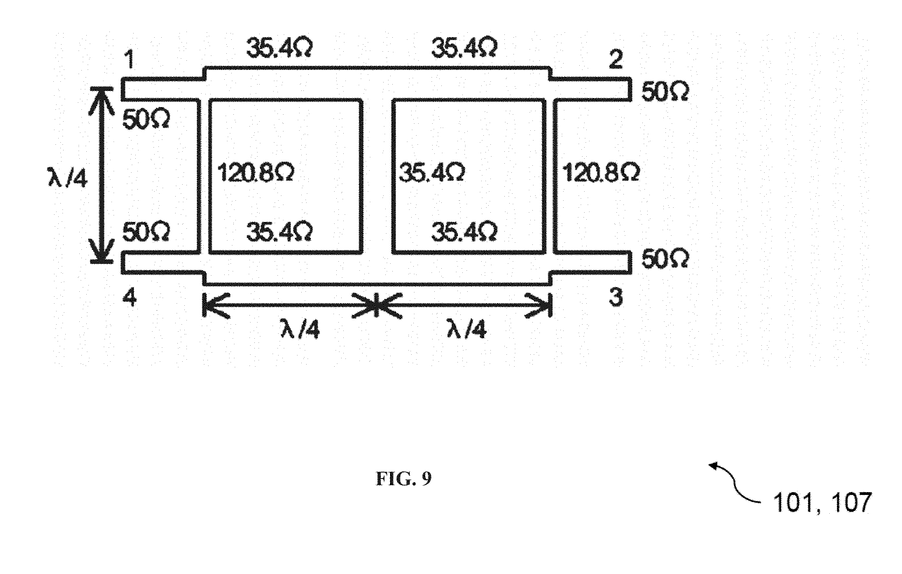

FIG. 9 shows a diagram of a first directional coupler and/or a second directional coupler according to an embodiment;

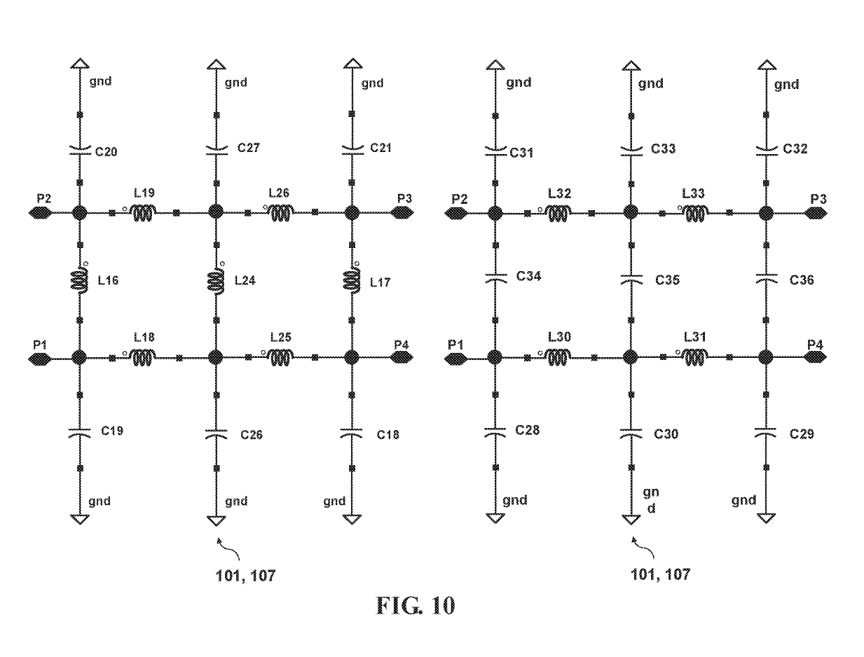

FIG. 10 shows diagrams of a first directional coupler and/or a second directional coupler according to different embodiments;

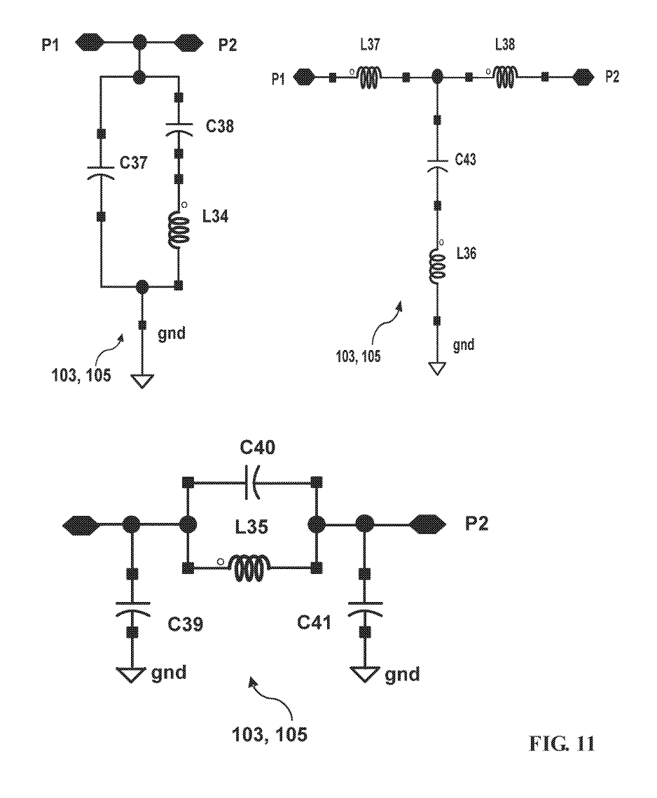

FIG. 11 shows diagrams of a first filter and/or a second filter according to different embodiments;

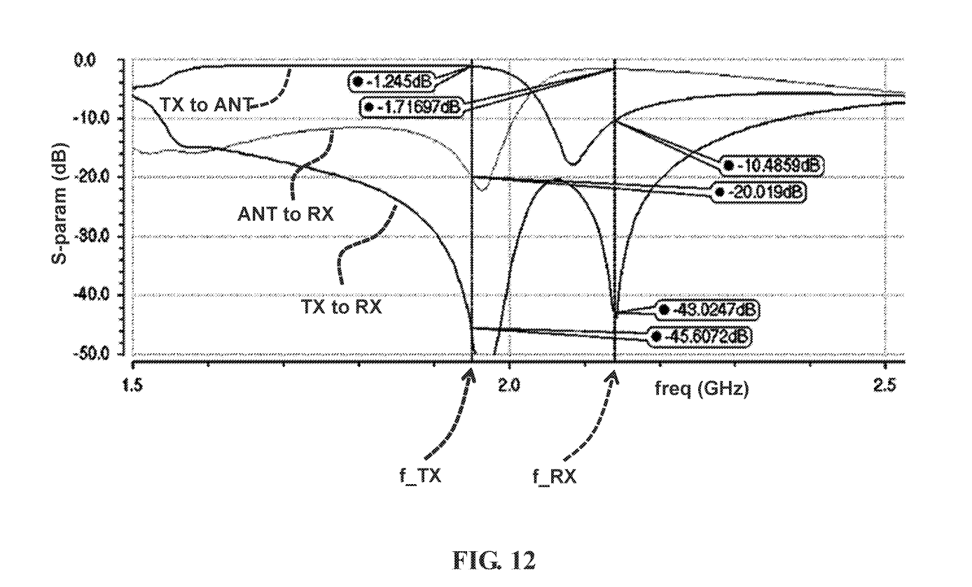

FIG. 12 shows a performance diagram of a RF duplexer according to an embodiment;

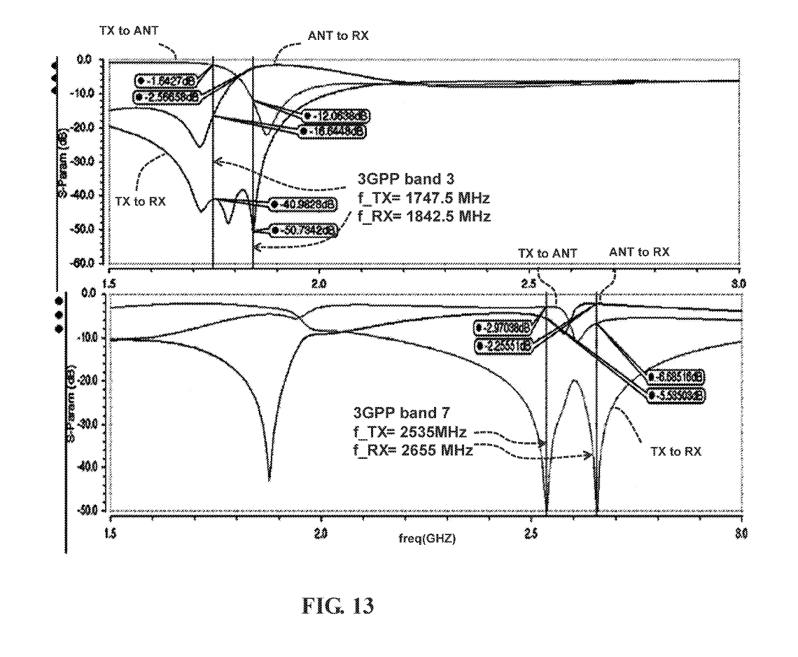

FIG. 13 shows performance diagrams of a RF duplexer according to an embodiment; and

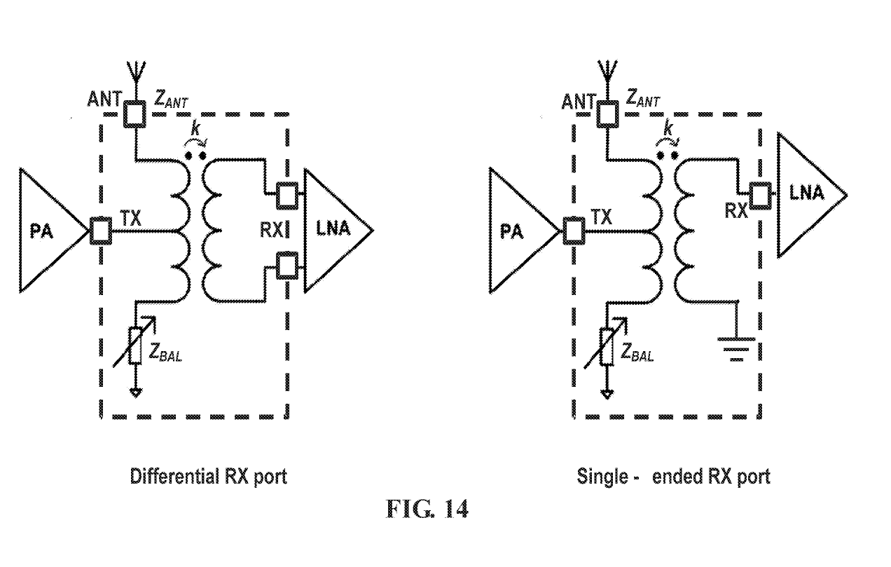

FIG. 14 shows diagrams of transformer based RF duplexers having different reception ports.

### DETAILED DESCRIPTION OF EMBODIMENTS

FIG. 1 shows a diagram of a RF duplexer 100 for handling an input reception signal according to an embodiment. The RF duplexer 100 comprises a first directional coupler 101 being configured to divide the input reception signal into a first auxiliary reception signal and a second auxiliary reception signal, wherein the first auxiliary reception signal and the second auxiliary reception signal comprise signal components at a reception frequency, a first filter 103 being configured to filter the first auxiliary reception signal to obtain a third auxiliary reception signal, wherein a pass band of the first filter 103 comprises the reception frequency, a second filter 105 being configured to filter the second auxiliary reception signal to obtain a fourth auxiliary reception signal, wherein a pass band of the second filter 105 comprises the reception frequency, and a second directional coupler 107 being configured to combine the third auxiliary reception signal with the fourth auxiliary reception signal to obtain an output reception signal.

In an embodiment of the RF duplexer 100, the first directional coupler 101 is configured to divide an input transmission signal into a first auxiliary transmission signal and a second auxiliary transmission signal, wherein the first auxiliary transmission signal and the second auxiliary transmission signal comprise signal components at a transmission frequency, the first filter 103 is configured to reflect the first auxiliary transmission signal to obtain a third auxiliary transmission signal, wherein a stop band of the first filter 103 comprises the transmission frequency, the second filter 105 is configured to reflect the second auxiliary transmission signal to obtain a fourth auxiliary transmission signal, wherein a stop band of the second filter 105 comprises the transmission frequency, and the first directional coupler 101 is configured to combine the third auxiliary transmission signal with the fourth auxiliary transmission signal to obtain an output transmission signal.

For sake of simplicity, the diagram of the RF duplexer 100 focuses on a reception path extending from an antenna port to a reception port of the RF duplexer 100. The input reception signal can be provided at the antenna port, and the output reception signal can be provided at the reception port. Analogously, the RF duplexer 100 can comprise a transmission port for providing the input transmission signal, wherein a transmission path can extend from the transmission port to the antenna port. The output transmission signal can be provided at the antenna port.

FIG. 2 shows a diagram of a RF frontend 200 according to an embodiment. The RF frontend 200 comprises a RF duplexer 100, wherein the RF duplexer 100 is configured to handle an input reception signal and to provide an output reception signal, and a low-noise amplifier 201 being configured to amplify the output reception signal. The RF duplexer 100 is a possible implementation of the RF duplexer 100 as described in conjunction with FIG. 1.

In an embodiment of the RF frontend 200, the RF frontend 200 further comprises a power amplifier being configured to provide an input transmission signal, wherein the RF duplexer 100 is configured to handle the input transmission signal and to provide an output transmission signal.

For sake of simplicity, the diagram of the RF frontend 200 focuses on a reception path of the RF duplexer 100, wherein the output reception signal is provided to the low-noise amplifier 201. Analogously, a transmission path of the RF duplexer 100 can be provided, wherein the input transmission signal can be provided by the power amplifier.

FIG. 3 shows a diagram of a method 300 according to an embodiment. The method 300 can handle an input reception signal. The method 300 can be performed by the RF duplexer 100 as described in conjunction with FIG. 1 and the RF frontend 200 as described in conjunction with FIG. 2. The method 300 comprises dividing step 301, by a first directional coupler 101, the input reception signal into a first auxiliary reception signal and a second auxiliary reception signal, wherein the first auxiliary reception signal and the second auxiliary reception signal comprise signal components at a reception frequency, filtering step 303, by a first filter 103, the first auxiliary reception signal to obtain a third auxiliary reception signal, wherein a pass band of the first filter 103 comprises the reception frequency, filtering step 305, by a second filter 105, the second auxiliary reception signal to obtain a fourth auxiliary reception signal, wherein a pass band of the second filter 105 comprises the reception frequency, and combining step 307, by a second directional coupler 107, the third auxiliary reception signal with the fourth auxiliary reception signal to obtain an output reception signal.

In an embodiment of the method 300, the method 300 further comprises dividing, by the first directional coupler 101, an input transmission signal into a first auxiliary transmission signal and a second auxiliary transmission signal, wherein the first auxiliary transmission signal and the second auxiliary transmission signal comprise signal components at a transmission frequency, reflecting, by the first filter 103, the first auxiliary transmission signal to obtain a third auxiliary transmission signal, wherein a stop band of the first filter 103 comprises the transmission frequency, reflecting, by the second filter 105, the second auxiliary transmission signal to obtain a fourth auxiliary transmission signal, wherein a stop band of the second filter 105 comprises the transmission frequency, and combining, by the first directional coupler 101, the third auxiliary transmission signal with the fourth auxiliary transmission signal to obtain an output transmission signal.

The steps of the method 300 can be performed in any order and can be performed in sequence and/or in parallel. For example, filtering step 303 the first auxiliary reception signal and filtering step 305 the second auxiliary reception signal can be performed simultaneously, and can consequently form two parallel paths in the diagram. Analogously, reflecting the first auxiliary transmission signal and reflecting the second auxiliary transmission signal can be performed simultaneously, and can consequently form two parallel paths in the diagram.

Further embodiments of the RF duplexer 100, the RF frontend 200, and the method 300 are described in more detail in the following.

FIG. 4 shows a diagram of a RF frontend 200 according to an embodiment. The RF frontend 200 comprises a RF duplexer 100, wherein the RF duplexer 100 comprises a first directional coupler 101, a first filter 103, a second filter 105, a second directional coupler 107, and a tunable load (TL) 401. The first directional coupler 101 and the second directional coupler 107 can be quadrature hybrid (QH) couplers. The RF duplexer 100 further comprises an antenna (ANT) port, a reception (RX) port, and a transmission (TX) port. The RF frontend 200 further comprises a low noise amplifier (LNA) 201, a power amplifier (PA) 403, an antenna tuner (AT) 405, and an antenna 407. The RF frontend 200 forms a possible implementation of the RF frontend 200 as described in conjunction with FIG. 2.

The RF duplexer 100 comprises two directional couplers 101, 107, which can be realized as QH couplers, and two filters 103, 105. The two directional couplers 101, 107 and the two filters 103, 105 can be identical, respectively. The ANT port-to-RX port path can rely on a transmission through the filters 103, 105, and the TX port-to-ANT port path can rely on a reflection at the filters 103, 105. This architecture uses moderately frequency-selective components, in particular the filters 103, 105. This way, a systematic 3 dB loss limit can be overcome. Furthermore, a filtering is added, which can help to be less sensitive with regard to antenna impedance variations.

The two directional couplers 101, 107 can separate the auxiliary signals transmitted through the filters 103, 105 from the reflected auxiliary signals. An isolation between the TX port and the RX port can be provided by the two directional couplers 101, 107, in particular when realized as QH couplers. An isolation of e.g. 40 dB or more can be realized. In particular, destructive superposition of the third and fourth auxiliary transmission signals within the RF duplexer 100 can allow for this high amount of isolation. Additionally, a filtering can be provided in the RX port-to-ANT port path as well as the ANT port-to-RX port path by the filters 103, 105. A filtering of e.g. 5 to 20 dB can be realized.

FIG. 5 shows a diagram of a RF frontend 200 according to an embodiment. The RF frontend 200 comprises a RF duplexer 100, wherein the RF duplexer 100 comprises a first directional coupler 101, a first filter 103, a second filter 105, a second directional coupler 107, and a tunable load 401. The first directional coupler 101 and the second directional coupler 107 can be QH couplers. The RF frontend 200 further comprises a LNA 201, a PA 403, an AT 405, and an antenna 407. The RF frontend 200 forms a possible implementation of the RF frontend 200 as described in conjunction with FIG. 2.

The diagram shows a low-cost implementation of the RF duplexer 100 and the RF frontend 200, wherein up to 18 digitally tunable capacitors (DTCs) are used, i.e. up to seven for each directional coupler 101, 107 and two for each filter 103, 105. The RF duplexer 100 and the RF frontend 200 can be realized on a SOI and/or MEMS die. Components of the two directional couplers 101, 107 and/or the two filters 103, 105 can be realized using SMD technology. In an embodiment, the sum of transmission loss and reception loss of the RF duplexer is less than 4 dB.

The inductors of the directional couplers 101, 107 can be realized on a SOI die and/or in IPD technology. The inductors of the filters 103, 105 can be realized in IPD and/or SMD technology. The DTCs can be realized in SOI technology.

In high-performance implementations, the inductors of the directional couplers 101, 107 can be realized in SMD and/or in IPD technology. The inductors and/or resonators of the filters 103, 105 can be realized in IPD technology as well, or using SAW or BAW technology. The DTCs can be realized in SOI or MEMS technology.

In an embodiment of the RF duplexer 100, the digitally tunable capacitors are digitally controlled by a processor. The processor can be comprised by the RF duplexer 100 or the RF frontend 200. This can allow for an efficient adjustment or selection of frequency bands.

FIG. 6 shows a diagram of a first directional coupler 101 and/or a second directional coupler 107 according to an embodiment. The first directional coupler 101 and/or the second directional coupler 107 comprise four ports. The first directional coupler 101 and/or the second directional coupler 107 can be QH couplers.

The first directional coupler 101 and/or the second directional coupler 107 can comprise a plurality of transmission lines, e.g. microstrips. Using transmission lines can lead to a low loss assuming a given Q factor of inductors and capacitors. The transmission lines have different characteristic impedances Zp and Zr. The transmission lines can form series arms and shunt arms.

The transmission lines can be quarter-wavelength (λ/4) transmission lines and/or slow-wave transmission lines, wherein slow-wave transmission lines can artificially increase a series inductance and/or shunt capacitance per length. Transmission lines may particularly be advantageous when implemented within a MMIC.

FIG. 7 shows diagrams of a first directional coupler 101 and/or a second directional coupler 107 according to different embodiments. The first directional coupler 101 and/or the second directional coupler 107 comprise four ports P1, P2, P3, and P4 and are referenced to ground potential (gnd). The first directional coupler 101 and/or the second directional coupler 107 are realized using lumped components.

The left diagram depicts an equivalent circuit using lumped components. The equivalent circuit can be considered as a direct translation of a transmission line based directional coupler into a circuit using lumped components, wherein each transmission line is replaced by a pi-network comprising a shunt capacitor, a series inductor and a shunt capacitor.

The middle diagram depicts an equivalent circuit using lumped components, wherein the vertical lines may be inverted with respect to the left diagram. The horizontal lines use a shunt-C, series-L, shunt-C pi-network. The vertical lines can use a shunt-L, series-C, shunt-L pi-network, wherein the shunt-L can be absorbed in the shunt-C of the horizontal pi-networks by decreasing their capacitance C1. The middle diagram forms a mixture of the left diagram and the right diagram.

The right diagram depicts an equivalent circuit using lumped components, wherein the horizontal lines may be inverted with respect to the middle diagram. The right diagram forms an inverted version of the left diagram, wherein each capacitor is replaced by an inductor, and vice versa. The behavior can be identical, wherein the output signals can lead in phase by 90 degree and 180 degree compared to the input signal, while they may lag compared to the left diagram.

FIG. 8 shows diagrams of a first directional coupler 101 and/or a second directional coupler 107 according to different embodiments. The first directional coupler 101 and/or the second directional coupler 107 are transformer based directional couplers. The first directional coupler 101 and/or the second directional coupler 107 can be QH couplers. The first directional coupler 101 and/or the second directional coupler 107 comprise four ports 1, 2, 3, and 4.

The upper diagram depicts an equivalent circuit comprising a single transformer stage. The lower diagram depicts an equivalent circuit comprising two transformer stages.

FIG. 9 shows a diagram of a first directional coupler 101 and/or a second directional coupler 107 according to an embodiment. The first directional coupler 101 and/or the second directional coupler 107 comprise four ports 1, 2, 3, and 4. The first directional coupler 101 and/or the second directional coupler 107 can be QH couplers. The first directional coupler 101 and/or the second directional coupler 107 can be multi-section directional couplers, in particular dual-section directional couplers. Multi-section directional couplers can have an increased bandwidth compared to single-section directional couplers.

The first directional coupler 101 and/or the second directional coupler 107 can comprise a plurality of transmission lines, e.g. microstrips. Using transmission lines can lead to a low loss assuming a given Q factor of inductors and capacitors. The transmission lines have different characteristic impedances.

The transmission lines can be W24 transmission lines and/or slow-wave transmission lines, wherein slow-wave transmission lines can artificially increase a series inductance and/or shunt capacitance per length. Transmission lines may particularly be advantageous when implemented within a MMIC.

FIG. 10 shows diagrams of a first directional coupler 101 and/or a second directional coupler 107 according to different embodiments. The first directional coupler 101 and/or the second directional coupler 107 comprise four ports P1, P2, P3, and P4 and are referenced to gnd. The first directional coupler 101 and/or the second directional coupler 107 are realized using lumped components.

The left diagram depicts an equivalent circuit using lumped components. The left diagram relates to a translation of the diagram in FIG. 9 into a lumped circuit, wherein each line is replaced by a shunt-C, series-L, and shunt-C equivalent circuit. Here, seven inductors and six capacitors are employed.

The right diagram depicts an equivalent circuit using lumped components, wherein the vertical lines may be inverted with respect to the left diagram. Fewer inductors can be used when inverting the three vertical lines, e.g. four inductors instead of seven inductors.

FIG. 11 shows diagrams of a first filter 103 and/or a second filter 105 according to different embodiments. The first filter 103 and/or the second filter 105 comprise two ports P1, P2 and are referenced to gnd. The first filter 103 and/or the second filter 105 are realized using lumped components.

The left diagram relates to a shunt filter having a parallel and a series resonance. It can reflect at its series resonance frequency having low shunt impedance, and can transmit at its parallel resonance frequency having high shunt impedance.

The middle diagram relates to a specific filter. It can reflect at the resonance frequency of the parallel resonator having high series impedance, and can transmit at a slightly lower frequency, where the shunt capacitors compensate the impedance transformation of the inductive resonator.

The right diagram relates to a specific filter. It can reflect at the resonance frequency of the series resonator having low shunt impedance, and can transmit at a slightly lower frequency, where the series inductors compensate the capacitance of the shunt resonator.

Many more implementations are possible, in particular pi-topologies instead of T-topologies, as well as higher order filters. Generally, the filters 103, 105 can have the frequency of maximum reflection below the frequency of maximum transmission.

FIG. 12 shows a performance diagram of a RF duplexer 100 according to an embodiment. The diagram indicates magnitudes of scattering parameters (S-parameters) between a RX port, a TX port, and an ANT port of a RF duplexer 100 over frequency. The diagram further indicates a reception frequency (f_{—RX}) and a transmission frequency (f_{—TX}).

The scattering parameters are simulated for 3GPP band 1, having a transmission frequency f_{—TX}=1.95 gigahertz (GHz) and a reception frequency f_{—RX}=2.13 GHz. In this example, the transmission loss and the reception loss are as low as 1.25 dB and 1.72 dB, respectively, compared to e.g. 3 to 4 dB using a transformer-based duplexer.

FIG. 13 shows performance diagrams of a RF duplexer 100 according to an embodiment. The diagrams indicate magnitudes of S-parameters between a RX port, a TX port, and an ANT port of a RF duplexer 100 over frequency. The diagrams further indicate reception frequencies (f_{—RX}) and transmission frequencies (f_{—TX}).

The diagrams show s-parameters for 3GPP bands 3 and 7, and demonstrate that a single RF duplexer 100 can handle all 3GPP bands from 1.7 to 2.7 GHz. Both simulations (3GPP band 3 and 3GPP band 7) have been performed with regard to the same RF duplexer 100, wherein the only difference between the simulations was the digital setting of the respective digitally tunable capacitors.

FIG. 14 shows diagrams of transformer based RF duplexers having different reception ports. The transformer based RF duplexers comprise a RX port, a TX port, and an ANT port, and are connected to an LNA, a PA, and an ANT having antenna impedance Z_{ANT}. The transformer based RF duplexers further comprise balance impedances Z_{BAL}. The coupling factor between a primary winding and a secondary winding of the transformers is denoted by k. The transformer based RF duplexers can be tunable.

The left diagram depicts a transformer based RF duplexer having a differential reception port. Within this transformer based RF duplexer, there can be a high common mode TX port leakage to the RX port, even if the transmission signal cancels perfectly differentially at the RX port. This can compress, or at least degrade, the linearity of the LNA.

The right diagram depicts a transformer based RF duplexer having a single-ended reception port. The balance impedance Z_{BAL} can track the antenna impedance Z_{ANT} over time and frequency. In this case, the signal of the PA can cancel at the input of the LNA, while it can be split 50 percent to the antenna and 50 percent into the balance impedance Z_{BAL}. Similarly, the RX port signal can be split, 50 percent to the input of the LNA, and 50 percent to the balance impedance Z_{BAL}. This 50 percent, or 3 dB, power splitting can be a lower limit for loss of this topology.

In summary, the invention relates to a RF duplexer 100 comprising two directional couplers 101, 107, e.g. tunable QH couplers, and two filters 103, 105, e.g. similar or identical tunable filters. The RF duplexer 100 can be integrated into a single package using a multi-die. The RF duplexer 100 can be integrated in semiconductor technology using a single-die. The directional couplers 101, 107 can be realized using any of the described options. The filters 103, 105 can be realized using any of the described options. The RF duplexer 100 can comprise a tunable load 401 connected to the isolated port of the second directional coupler 107 instead of a termination resistor.

The invention further relates to a RF frontend 200, e.g. a FEM comprising a RF duplexer 100 and any of the following components: an LNA 201 connected to an RX port of the RF duplexer 100, a PA 403 connected to a TX port of the RF duplexer 100, an AT 405 connected to an ANT port the RF duplexer 100, and/or a RF switch connected to any of the ports the RF duplexer 100.

The RF duplexer 100 and the RF frontend 200 can be realized using different technologies. In particular, the DTCs may be implemented in SOI or MEMS technology. The inductors may be implemented in SOI technology, may use bond wires, and may use routing layers inside a package, e.g. in a ball-grid-array (BGA) package. They may further be implemented in IPD and/or SMD technology. The filters 103, 105 can comprise resonators implemented in SAW technology, BAW technology, or IPD technology. The directional couplers 101, 107, e.g. QH couplers, can be transmission line based directional couplers and can employ slow-wave transmission lines. The invention can allow for a variety of advantages compared to transformer based RF duplexers.

Although the disclosure and its advantages have been described in detail, it should be understood that various changes, substitutions and alterations can be made herein without departing from the spirit and scope of the invention as defined by the appended claims.

1. A radio frequency duplexer, comprising:
a first directional coupler configured to divide an input reception signal into a first auxiliary reception signal and a second auxiliary reception signal, wherein the first auxiliary reception signal and the second auxiliary reception signal comprise signal components at a reception frequency;
a first filter coupled to the first directional coupler, wherein the first filter is configured to filter the first auxiliary reception signal to obtain a third auxiliary reception signal, and wherein a pass band of the first filter comprises the reception frequency;
a second filter coupled to the first directional coupler, wherein the second filter is configured to filter the second auxiliary reception signal to obtain a fourth auxiliary reception signal, and wherein a pass band of the second filter comprises the reception frequency; and
a second directional coupler configured to combine the third auxiliary reception signal with the fourth auxiliary reception signal to obtain an output reception signal.

2. The radio frequency duplexer of claim 1, wherein the first directional coupler is configured to divide an input transmission signal into a first auxiliary transmission signal and a second auxiliary transmission signal, wherein the first auxiliary transmission signal and the second auxiliary transmission signal comprise signal components at a transmission frequency; wherein the first filter is configured to reflect the first auxiliary transmission signal to obtain a third auxiliary transmission signal, wherein a stop band of the first filter comprises the transmission frequency, wherein the second filter is configured to reflect the second auxiliary transmission signal to obtain a fourth auxiliary transmission signal, wherein a stop band of the second filter comprises the transmission frequency, and wherein the first directional coupler is configured to combine the third auxiliary transmission signal with the fourth auxiliary transmission signal to obtain an output transmission signal.

3. The radio frequency duplexer of claim 1, wherein the first directional coupler or the second directional coupler is a quadrature hybrid coupler.

4. The radio frequency duplexer of claim 1, wherein at least one of the first filter or the second filter is a band-pass filter, a low-pass filter, a high-pass filter, or a notch filter.

5. The radio frequency duplexer of claim 1, wherein the first directional coupler and the second directional coupler are identical, or wherein the first filter and the second filter are identical.

6. The radio frequency duplexer of claim 1, further comprising a tunable load coupled to the second directional coupler, wherein the tunable load comprises a variable impedance.

7. The radio frequency duplexer of claim 1, wherein at least one of the first directional coupler or the second directional coupler is tunable.

8. The radio frequency duplexer of claim 7, wherein at least one of the first directional coupler or the second directional coupler comprises a plurality of digitally tunable capacitors.

9. The radio frequency duplexer of claim 1, wherein at least one of the first filter or the second filter is tunable.

10. The radio frequency duplexer of claim 9, wherein at least one of the first filter or the second filter comprises a plurality of digitally tunable capacitors.

11. The radio frequency duplexer of claim 1, wherein the first directional coupler, the second directional coupler, the first filter, or the second filter comprises a plurality of transmission lines.

12. A radio frequency frontend, comprising:
a radio frequency duplexer comprising:
a first directional coupler;
a first filter coupled to the first directional coupler;
a second filter coupled to the first directional coupler; and
a second directional coupler coupled to the first filter and coupled to the second filter, wherein the radio frequency duplexer is configured to handle an input reception signal and to provide an output reception signal; and
a low-noise amplifier configured to amplify the output reception signal.

13. The radio frequency frontend of claim 12, further comprising a power amplifier configured to provide an input transmission signal, wherein the radio frequency duplexer is configured to handle the input transmission signal and to provide an output transmission signal.

14. The radio frequency frontend of claim 12, further comprising a radio frequency switch, wherein the radio frequency switch is configured to route the output reception signal from the radio frequency duplexer to the low-noise amplifier.

15. A method for handling a signal, comprising:
dividing an input reception signal into a first auxiliary reception signal and a second auxiliary reception signal, wherein the first auxiliary reception signal and the second auxiliary reception signal comprise signal components at a reception frequency;
filtering the first auxiliary reception signal to obtain a third auxiliary reception signal, wherein a pass band of the first filter comprises the reception frequency;
filtering the second auxiliary reception signal to obtain a fourth auxiliary reception signal, and wherein a pass band of the second filter comprises the reception frequency; and
combining the third auxiliary reception signal with the fourth auxiliary reception signal to obtain an output reception signal.

16. The method of claim 15, further comprising:
dividing an input transmission signal into a first auxiliary transmission signal and a second auxiliary transmission signal, wherein the first auxiliary transmission signal and the second auxiliary transmission signal comprise signal components at a transmission frequency;
reflecting the first auxiliary transmission signal to obtain a third auxiliary transmission signal, wherein a stop band of the first filter comprises the transmission frequency;
reflecting the second auxiliary transmission signal to obtain a fourth auxiliary transmission signal, and wherein a stop band of the second filter comprises the transmission frequency; and
combining the third auxiliary transmission signal with the fourth auxiliary transmission signal to obtain an output transmission signal.

17. The radio frequency frontend of claim 12, wherein the first directional coupler is configured to divide an input reception signal into a first auxiliary reception signal and a second auxiliary reception signal, and wherein the first auxiliary reception signal and the second auxiliary reception signals comprise signal components at a reception frequency.

18. The radio frequency frontend of claim 17, wherein the first filter is configured to filter the first auxiliary reception signal to obtain a third auxiliary reception signal, wherein a pass band of the first filter comprises the reception frequency, wherein the second filter is configured to filter the second auxiliary reception signal to obtain a fourth auxiliary reception signal, and wherein a pass band of the second filter comprises the reception frequency.

19. The radio frequency frontend of claim 18, wherein the second directional coupler is configured to combine the third auxiliary reception signal with the fourth auxiliary reception signal to obtain the output reception signal, and wherein the radio frequency duplexer is configured to handle the input reception signal and to provide the output reception signal

20. The radio frequency frontend of claim 12, wherein at least one of the first directional coupler or the second directional coupler is a quadrature hybrid coupler.
